(19) United States
(12) Patent Application Publication
(10) Pub. No.: US 2025/0242457 A1
(43) Pub. Date: Jul. 31, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Yutaka MOMIYAMA, Fukuoka (JP); Ikuo ITAKURA, Fukuoka (JP); Hitoshi SASAKI, Fukuoka (JP)

(21) Appl. No.: 19/034,353

(22) Filed: Jan. 22, 2025

(30) Foreign Application Priority Data
Jan. 25, 2024 (JP) 2024-009230

(51) Int. Cl. B23Q 3/15; F16J 15/02; H02N 13/00

(52) U.S. Cl. CPC B23Q 3/15; F16J 15/02; H02N 13/00

(57) ABSTRACT

An electrostatic chuck includes a dielectric substrate, an attraction electrode provided inside the dielectric substrate, and an RF electrode provided inside the dielectric substrate. The RF electrode is provided in a range where an outer circumferential edge of the RF electrode is positioned inside an outer circumferential edge of the attraction electrode in top view.

### CROSS-REFERENCE TO RELATED APPLICATION

This application is based upon and claims the benefit of priority from Japanese Patent Application No. 2024-009230 filed on Jan. 25, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held. The attraction electrode may sometimes be formed on a surface of the dielectric substrate on the base plate side, but is often provided inside the dielectric substrate.

As described in Japanese Patent Laid-Open No. 2011-119654, an RF electrode may be embedded inside the dielectric substrate in addition to the attraction electrode. The RF electrode functions as one of a pair of counter electrodes for generating plasma in a semiconductor manufacturing apparatus.

### SUMMARY

When a process such as etching is performed on the substrate, Joule heat is generated in the RF electrode and increases temperature of surrounding members in some cases. Accordingly, the RF electrode can act as a heat generating source during the process. Conventionally, how to dispose the RF electrode as a heat generating source to reduce variation in an in-plane temperature distribution of the wafer during the process has not been specifically discussed.

The present invention has been made in view of the above-mentioned issue and is aimed to provide an electrostatic chuck which can reduce variation in an in-plane temperature distribution of a wafer during a process.

To address the above-described problem issue, an electrostatic chuck according to the present invention includes a dielectric substrate including a placement surface on which an object to be attracted is placed, an attraction electrode provided inside the dielectric substrate, and an RF electrode provided inside the dielectric substrate. The RF electrode is provided in a range where an outer circumferential edge of the RF electrode is positioned inside an outer circumferential edge of the attraction electrode when viewed from a direction perpendicular to the placement surface.

It is known that, during a process such as etching, temperature of a part of the wafer on an outer circumferential side, in particular, tends to be high. Thus, in the electrostatic chuck with the above-described configuration, the RF electrode as a heat generating source is provided in a range where the outer circumferential edge of the RF electrode is positioned inside the outer circumferential edge of the attraction electrode, and thus temperature increase at the part of the wafer on the outer circumferential side can be reduced. Accordingly, variation in an in-plane temperature distribution of the substrate during the process can be reduced as compared to conventional cases.

According to the present invention, it is possible to provide an electrostatic chuck which can reduce variation in an in-plane temperature distribution of a substrate during a process.

### BRIEF DESCRIPTION OF THE DRAWINGS

FIG. 1 is a cross-sectional view schematically illustrating a configuration of an electrostatic chuck according to the present embodiment; and

FIG. 2 is an expanded and detailed view of a part of the configuration in FIG. 1.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

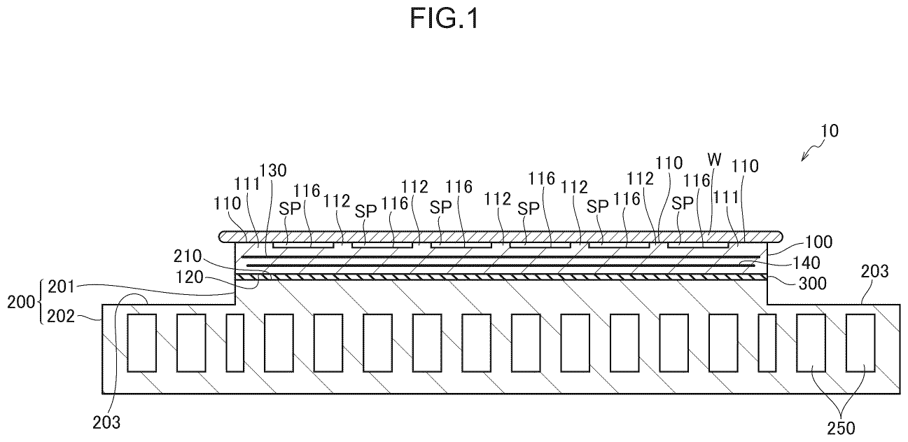

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus. A diameter of the dielectric substrate 100 is, for example, 290 to 300 mm. A thickness of the dielectric substrate 100 is, for example, 0.5 to 3.0 mm.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various configurations in related art can be adopted. The single attraction electrode 130 may be provided as so-called a “monopolar” electrode as in the present embodiment, but may also include two attraction electrodes as so-called “bipolar” electrodes. A depth of a position where the attraction electrode 130 is arranged, that is, a distance from a bottom 116 which will be described below to the attraction electrode 130 is, for example, 0.1 to 0.5 mm.

In addition to the above-described attraction electrode 130, an RF electrode 140 is embedded inside the dielectric substrate 100. The RF electrode 140 is provided as one of a pair of counter electrodes for generating plasma in the semiconductor manufacturing apparatus. The other of the counter electrodes is provided at a position on an upper side of the electrostatic chuck 10 in the semiconductor manufacturing apparatus. When a high-frequency alternating-current voltage is applied between these counter electrodes, plasma is generated on the upper side of the wafer W and used for processing such as deposition and etching on the wafer W.

Similar to the attraction electrode 130, the RF electrode 140 is a thin planar layer made of a metallic material such as tungsten, for example. As a material of the RF electrode 140, molybdenum, platinum, palladium, and the like may be used in addition to tungsten. The RF electrode 140 is embedded at a position on the surface 120 side of the attraction electrode 130. Similar to the attraction electrode 130, the RF electrode 140 is disposed in parallel to the surface 110. The RF electrode 140 is a single electrode which is substantially circular in top view. In top view, a center of the RF electrode 140 matches a center of the dielectric substrate 100. A distance from the attraction electrode 130 to the RF electrode 140 is, for example, 0.2 to 2 mm. A distance from the RF electrode 140 to the surface 120 is, for example, 0.1 to 2.5 mm.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A tip (upper end in FIG. 1) of the seal ring 111 serves as a part of the surface 110 and contacts the wafer W. Specifically, the tip of the seal ring 111 is a part closest to an outer circumferential side on the surface 110 which serves as the placement surface.

It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by the reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A tip of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a “surface to be joined” which is joined to the dielectric substrate 100 via the joining layer 300.

The joining layer 300 is a layer provided between the dielectric substrate 100 and the base plate 200 to join those components. The joining layer 300 is provided by causing an adhesive made of an insulating material to be cured. According to the present embodiment, a silicone adhesive is used as the above-described adhesive. It is noted however that the joining layer 300 may be provided by causing an adhesive made of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal splaying can be used. When the surface of the base plate 200 is covered by the insulating film, it is possible to increase a withstand voltage of the base plate 200.

The base plate 200 includes a support section 201 and a flange section 202. The support section 201 is an upper part in FIG. 1 of the base plate 200 and is a substantially cylindrical part which directly supports the dielectric substrate 100 from below. A diameter of the support section 201, that is, a diameter of the surface 210 may be the same as the diameter of the dielectric substrate 100 but may be slightly smaller than the diameter of the dielectric substrate 100. The diameter of the support section 201 is, for example, 290 to 300 mm. A thickness of the support section 201, that is, an amount of protrusion of the support section 201 which faces upwards in FIG. 1 (amount of protrusion from the flange section 202) is, for example, 3 to 15 mm.

The flange section 202 is, in FIG. 1, a lower part of the base plate 200. A shape of the flange section 202 is a substantially cylindrical shape, and a central axis of the flange section 202 matches a central axis of the support section 201. A diameter of the flange section 202 is larger than the diameter of the support section 201. An amount of protrusion of the flange section 202 from a lateral surface of the support section 201 (that is, an amount of protrusion in a radial direction) is, for example, 20 to 30 mm. A thickness of the flange section 202 is, for example, 25 to 40 mm. An entire thickness of the base plate 200 including the support section 201 and the flange section 202 is, for example, 30 to 40 mm.

When a process on the wafer W is to be performed in the semiconductor manufacturing apparatus, a focus ring which is not illustrated in the drawing is installed on an upper surface 203 of the flange section 202. The focus ring is an annular and plate-like member made of an insulating material such as quartz, for example, and is installed for a purpose of regulating a distribution of plasma during the process. A state is established in which almost the whole of the dielectric substrate 100 and the support section 201 is surrounded by the focus ring from an outer circumferential side.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant.

It is known that, during a process such as etching, temperature of a part of the wafer W on the outer circumferential side, in particular, tends to be higher. Thus, the electrostatic chuck 10 of the present embodiment is provided with various kinds of modifications described below to reduce local temperature increase as described above and make an in-plane temperature distribution of the wafer W as uniform as possible during the process.

As illustrated in FIG. 1, the coolant flow path 250 is routed not only in a part of the base plate 200 immediately below the wafer W but also in a part outside the part immediately below the wafer W. The non-illustrated focus ring and other members immediately above the upper surface 203 are cooled by the coolant passing through the outside part, and an outer circumferential side part of the wafer W is cooled as well through these members.

In the present embodiment, the diameter of the flange section 202 is relatively large. Since the flange section 202 is increased in size and the coolant flow path 250 is formed substantially entirely in the flange section 202 to circulate the coolant so that temperature increase at the outer circumferential side part of the wafer W can be reduced.

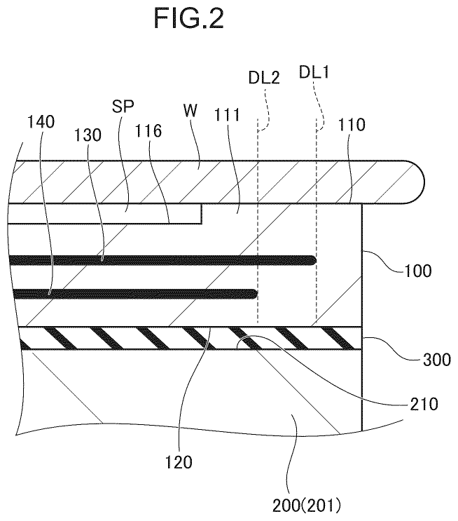

FIG. 2 illustrates a configuration of an outer circumferential edge of the dielectric substrate 100 and its vicinity part of the electrostatic chuck 10 in FIG. 1 in detail in an enlarged manner. A dotted line DL1 illustrated in FIG. 2 represents a position of an outer circumferential edge of the attraction electrode 130. A dotted line DL2 represents a position of an outer circumferential edge of the RF electrode 140. The “outer circumferential edge” of the attraction electrode 130 is a part where a smallest circle encompassing the entire attraction electrode 130 overlaps the attraction electrode 130 in top view. The “outer circumferential edge” of the RF electrode 140 is similarly defined.

To prevent dielectric breakdown, a distance from the outer circumferential edge (dotted line DL1) of the attraction electrode 130 to a lateral surface of the dielectric substrate 100 may be approximately 0.1 mm to 3 mm. A distance from the outer circumferential edge (dotted line DL2) of the RF electrode 140 to the lateral surface of the dielectric substrate 100 may be approximately 0.1 mm to 5 mm. As long as the above-described conditions are satisfied, a diameter of the outer circumferential edge of the RF electrode 140 may be smaller than a diameter of the outer circumferential edge of the attraction electrode 130. In other words, the RF electrode 140 may be provided in a range where the outer circumferential edge (dotted line DL1) of the RF electrode 140 is positioned inside the outer circumferential edge of the attraction electrode 130 (the dotted line DL2) in top view.

When a process is performed on the wafer W, Joule heat is generated in the RF electrode 140 and increases temperature of surrounding members in some cases. Accordingly, the RF electrode 140 can be a heat generating source during the process. Thus, in the present embodiment, as described above, the RF electrode 140 is provided in a range where the outer circumferential edge of the RF electrode 140 is positioned inside the outer circumferential edge of the attraction electrode 130. Since the RF electrode 140 as a heat generating source is provided in the above-described range, temperature increase at the part of the wafer W on the outer circumferential side can be reduced. Accordingly, variation in the in-plane temperature distribution of the wafer W during the process can be reduced.

The diameter of the outer circumferential edge of the attraction electrode 130 is larger than a diameter of the seal ring 111 on an inner circumferential side and smaller than a diameter of the seal ring 111 on the outer circumferential side. Accordingly, a part of the seal ring 111 overlaps the attraction electrode 130 in top view. When the seal ring 111 and the attraction electrode 130 overlap each other in top view, attraction force on the seal ring 111 increases, and the seal ring 111 and the wafer W closely adhere with strong force. Accordingly, heat resistance between the seal ring 111 and the wafer W decreases so that temperature increase of the wafer W immediately above the seal ring 111 can be reduced. As a result, variation in the in-plane temperature distribution of the wafer W during the process can be further reduced.

Not a part of the seal ring 111 but its entirety may overlap the attraction electrode 130 in top view. In this case, the diameter of the seal ring 111 on the outer circumferential side may be smaller than the diameter of the dielectric substrate 100 and smaller than the diameter of the outer circumferential edge of the attraction electrode 130.

The present embodiment has been described above with reference to the specific examples. However, the present disclosure is not limited to these specific examples. Configurations provided by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed;
an attraction electrode provided inside the dielectric substrate; and
an RF electrode provided inside the dielectric substrate, wherein
the RF electrode is provided in a range where an outer circumferential edge of the RF electrode is positioned inside an outer circumferential edge of the attraction electrode when viewed from a direction perpendicular to the placement surface.

2. The electrostatic chuck according to claim 1, wherein
the dielectric substrate is formed with a seal ring which is an annular protrusion with a tip serving as a part of the placement surface, and
at least part of the seal ring overlaps the attraction electrode when viewed from the direction perpendicular to the placement surface.
